(19) United States
(12) Patent Application Publication
(10) Pub. No.: US 2015/0311100 A1
(43) Pub. Date: Oct. 29, 2015

(54) LOAD PORT UNIT AND EFEM SYSTEM

(71) Applicant: TDK Corporation, Tokyo (JP)

(72) Inventors: Toshihiko MIYAJIMA, Tokyo (JP); Hiroshi IGARASHI, Tokyo (JP)

(73) Assignee: TDK Corporation, Tokyo (JP)

(21) Appl. No.: 14/259,797

(22) Filed: Apr. 23, 2014

(51) Int. Cl. H01L 21/673; H01L 21/677

(52) U.S. Cl. CPC H01L 21/67376; H01L 21/67742

(57) ABSTRACT

To suppress dust or the like from being drawn into a delivery zone when opening a lid of a pod in an EFEM system, a load port unit in the EFEM system includes a sealing member arranged on an external space side of a base, which defines a delivery zone and has an opening portion formed therein, and a sealing member arranged on the delivery zone side. A surface of a door that closes the opening portion on an external opening side protrudes toward the external space side with respect to an imaginary plane defined by a sealing region of the sealing member on the external opening side.

### BACKGROUND OF THE INVENTION

1. Field of the Invention

The present invention relates to a so-called equipment front end module (EFEM) system to be used in a semiconductor manufacturing process or the like when transporting a wafer held in a sealed transportation container referred to as a pod to a semiconductor processing apparatus or when transporting a wafer from the semiconductor processing apparatus to the pod, and further relates to a load port unit that actually performs opening and closing of a lid of the pod in the EFEM system.

2. Description of the Related Art

In recent years, in a semiconductor manufacturing process, there has generally been adopted a method of managing cleanliness throughout a process by maintaining a high cleanliness level in only three spaces including insides of various processing apparatus, a pod that contains a wafer and enables transportation of the wafer between the processing apparatus, and a mini-environment for performing delivery of a substrate from the pod to each of the processing apparatus. Such a pod includes a body unit that contains a wafer and has an opening formed on one side thereof so as to insert and remove the wafer, and a lid for closing the opening to secure a sealed space inside the pod. The mini-environment has a first opening portion configured to face the opening of the pod, and a second opening portion formed on the semiconductor processing apparatus side to face the first opening portion.

Air in an external periphery of such a mini-environment is cleaned by using a filter, and the clean air is introduced into the mini-environment. An apparatus for opening and closing the lid of the pod, the mini-environment, a mechanism for transporting a wafer, which is arranged in the mini-environment, and the like are collectively referred to as an EFEM system. Through use of the clean air cleaned by the filter, cleanliness of the mini-environment in the EFEM system is maintained to a predetermined level. However, a wiring pattern used in the semiconductor becomes finer along with a recent trend of downsizing and higher performance of the semiconductor, and hence more rigorous exclusion of influence of oxidation of the pattern is desired. For this reason, as disclosed in, for example, Japanese Patent Application Laid-Open No. 10-340874 and Japanese Patent No. 4,251,580, there has increasingly been adopted a configuration in which the mini-environment is set into a sealed space and the space is put under a nitrogen atmosphere with the purity maintained to a predetermined level or higher.

As described above, maintenance of the residual oxygen concentration and the cleanliness to predetermined levels can be easily achieved in the mini-environment by sealing the mini-environment and introducing or circulating an appropriate amount of nitrogen in the mini-environment, as instantiated in Japanese Patent Application Laid-Open No. 10-340874. However, the pod is transported through an external space with less cleanliness and mounted on a load port unit, and hence it is a concern that dust or the like penetrates into the mini-environment or the oxygen concentration is increased along with the opening and closing of the lid of the pod. As instantiated in Japanese Patent Application Laid-Open No. 10-340874, such a concern is not currently taken into consideration. In the configuration disclosed in Japanese Patent No. 4,251,580, a space is formed separately from the mini-environment, and the opening and closing of the lid of the pod is performed through the space so that dust is not introduced into the mini-environment. However, the configuration of the apparatus becomes complicated, and hence there is room for improvement in terms of cost, installation space, usage of nitrogen, and the like.

### SUMMARY OF THE INVENTION

The present invention has been made in view of the above-mentioned circumstances, and it is an object of the present invention to provide a load port unit as an interface that is reduced in amount of dust or the like penetrating into a mini-environment when opening and closing a lid of a pod and enhanced in cleanliness, and to provide an EFEM system including the load port unit.

In order to achieve the above-mentioned object, according to one embodiment of the present invention, there is provided a load port unit configured to remove a lid from a pod that contains an object therein, and to take the object from the pod to a delivery zone, the load port unit including: a base serving as a wall for isolating the delivery zone from an external space; an opening portion formed in the base; a door configured to open and close the opening portion, and to mount and remove the lid to and from the pod by fixing and unfixing the lid to and from the pod; a first sealing member configured to secure a tightness between the door and the base in the delivery zone; and a second sealing member configured to secure a tightness between the pod and the base in the external space, in which a surface of the door on the external space side protrudes toward the external space side with respect to an imaginary plane defined by a sealing region of the second sealing member.

It is preferred that the above-mentioned load port unit further include a synchronization control unit configured to drive the pod toward the opening portion in synchronization with an operation of the door after the door holds the lid in abutment against the lid.

Further, in order to achieve the above-mentioned object, according to one embodiment of the present invention, there is provided an equipment front end module (EFEM) system configured to be connected to a processing chamber for performing a process on an object via an interface on the processing chamber side, the EFEM system including: the interface on the processing chamber side; the above-mentioned load port unit; and an EFEM unit configured to supply an inert gas to the delivery zone by circulating the inert gas through a fan filter unit. In addition, it is preferred that the above-mentioned EFEM system further include a release valve configured to discharge an excess inert gas when a supply amount of the inert gas supplied to the delivery zone is excessive.

According to one embodiment of the present invention, it is possible to suppress the dust or the like from penetrating into the mini-environment when opening the lid of the pod, to transport a wafer between the pod and the semiconductor processing apparatus under an environment with higher cleanliness.

Further features of the present invention will become apparent from the following description of exemplary embodiments with reference to the attached drawings.

### BRIEF DESCRIPTION OF THE DRAWINGS

FIGS. 1A, 1B, 1C, and 1D are diagrams illustrating an exterior of an EFEM system according to an embodiment of the present invention. FIG. 1A is a front view of the system, FIG. 1B is a side view of the system on the left side, FIG. 1C is a side view of the system on the right side, and FIG. 1D is a top view of the system.

FIG. 2 is a schematic diagram illustrating a configuration of the EFEM system on a cross section cut along the plane 2-2 of FIG. 1D.

FIG. 3 is a schematic diagram illustrating a relationship among a port door, a base member, and a pod in a load port unit according to the embodiment illustrated in FIGS. 1A, 1B, 1C, and 1D.

FIGS. 4A, 4B, 4C, and 4D are diagrams illustrating a sequence of steps of removing a lid of the pod by the port door in the configuration illustrated in FIG. 3.

FIGS. 5A, 5B, 5C, and 5D are diagrams illustrating lid removing steps in a related-art configuration as a comparison to the present invention in a similar manner to the steps illustrated in FIGS. 4A, 4B, 4C, and 4D.

FIG. 6 is a block diagram illustrating a main circuit configuration of the EFEM system according to the present invention.

FIG. 7 is a flow chart illustrating an example of a switching step when supplying a gas.

### DESCRIPTION OF THE EMBODIMENTS

Preferred embodiments of the present invention will now be described in detail in accordance with the accompanying drawings.

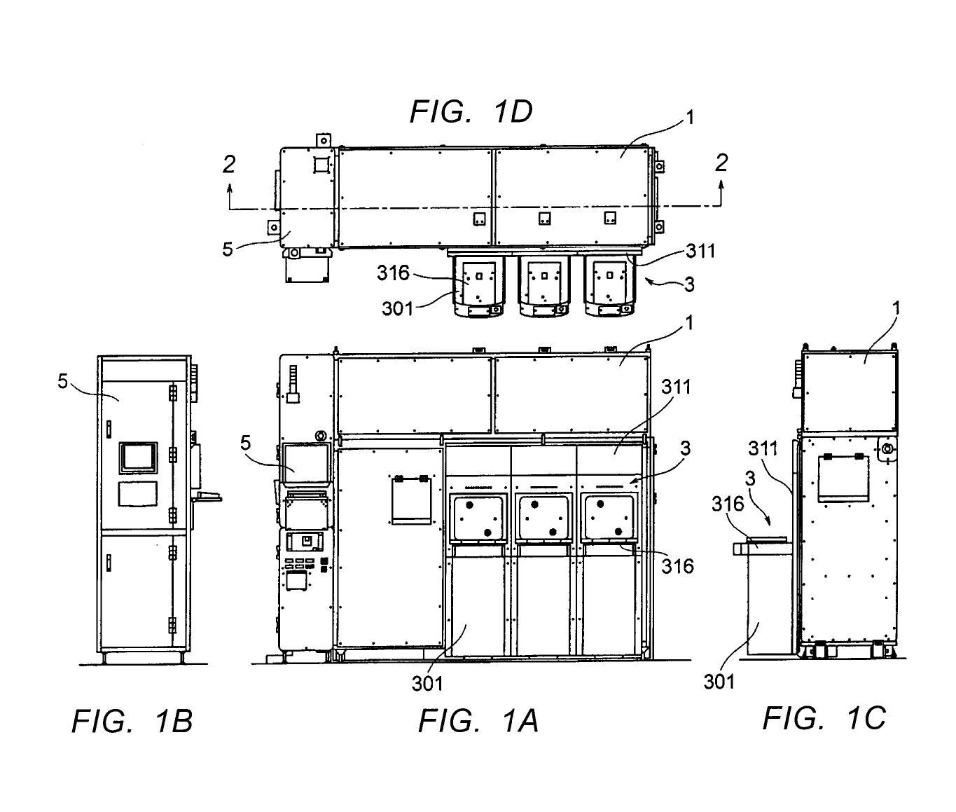

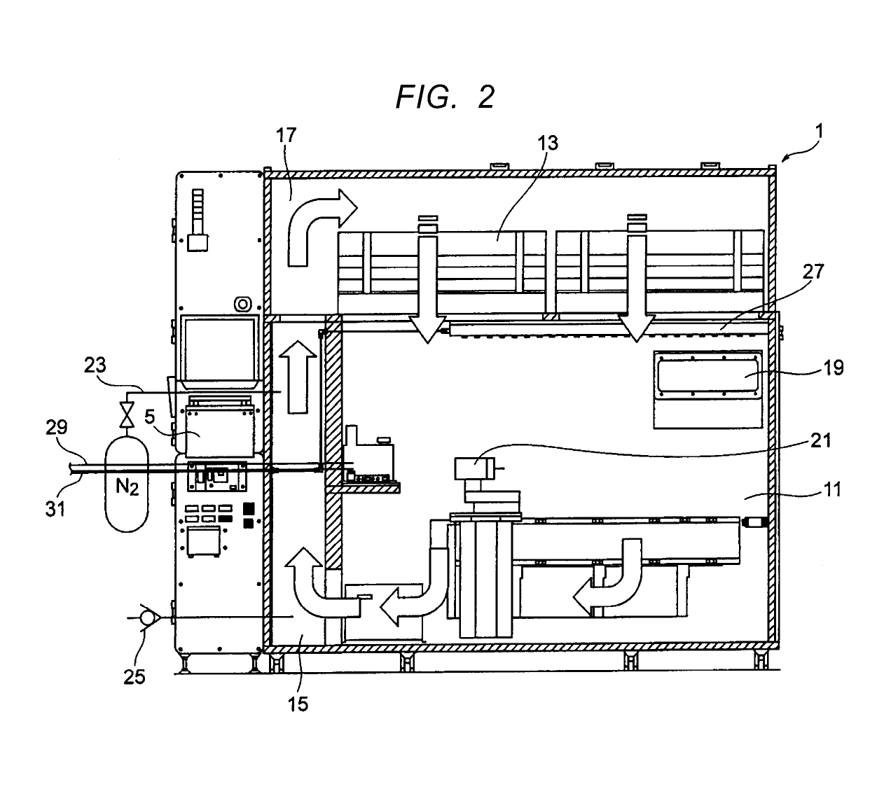

Exemplary embodiments of the present invention are described below with reference to the accompanying drawings. FIGS. 1A, 1B, 1C, and 1D are diagrams illustrating an exterior of an EFEM system 100 according to an embodiment of the present invention. FIG. 1A is a front view of the EFEM system, FIG. 1B is a side view of the EFEM system on the left side, FIG. 1C is a side view of the EFEM system on the right side, and FIG. 1D is a top view of the EFEM system. FIG. 2 is a schematic diagram illustrating an internal configuration of an EFEM unit on a cross section cut along the plane 2-2 of FIG. 1D.

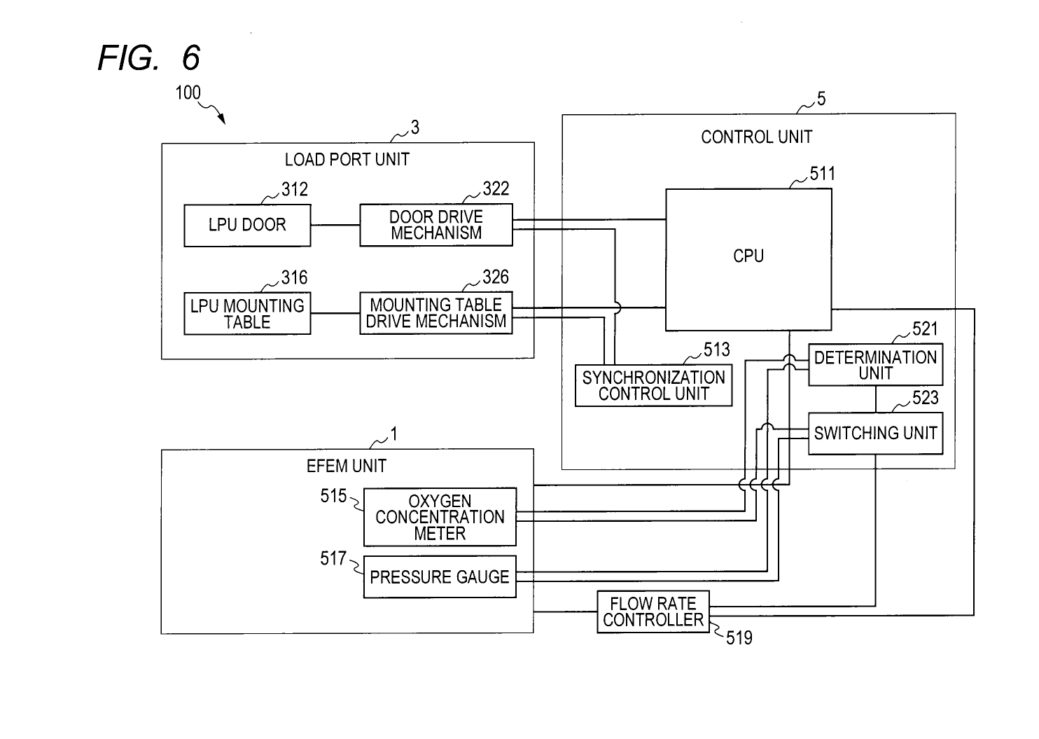

The EFEM system 100 according to this embodiment includes, as main constituent elements, an EFEM unit 1, a load port unit 3, and a control unit 5. The control unit 5 controls an operation of each of drive elements and the like described later with respect to the EFEM unit 1 and the load port unit 3. FIG. 6 is a block diagram illustrating a main circuit configuration of the EFEM system 100. As is described later, the load port unit 3 has a configuration for operating an LPU door 312 and an LPU mounting table 316. Operations of opening and closing of the LPU door 312 and holding and opening of a lid 402 of a pod by the LPU door 312 are performed by a door drive mechanism 322, and an operation of the LPU mounting table 316 for performing approach and separation of a pod 401 to and from an LPU base opening portion 315 under a state in which the pod 401 is mounted is performed by a mounting table drive mechanism 326. The control unit 5 includes a CPU 511 for controlling the operations of these drive mechanisms, and a synchronization control unit 513 described later for synchronizing these operations. The CPU 511 also executes control for supply of nitrogen in the EFEM unit 1 as described later.

The EFEM unit 1 includes a nitrogen circulating path, and a delivery zone 11 that is substantially a sealed space included in the circulating path. Nitrogen is supplied to the space by a nitrogen supply unit 23. The supply amount of nitrogen is controlled by a flow rate controller 519 (see FIG. 6) such as a mass flow controller, and the oxygen concentration in the internal space of the EFEM unit 1 is maintained to 1% or lower. Specifically, the nitrogen concentration is abruptly increased by supplying, for example, about 300 L/min of nitrogen at the initial stage of the operation of the EFEM unit 1, and after the nitrogen concentration reaches a predetermined level, the environment is maintained by supplying, for example, about 50 L/min of nitrogen. Excess nitrogen that has been excessively supplied is discharged by a release valve 25. That is, in the present invention, a gas supply unit for supplying a gas such as nitrogen (the nitrogen supply unit 23 in this embodiment) is configured to supply the gas with at least two types of flow rates including a high flow rate for decreasing the oxygen concentration and a low flow rate for maintaining a low oxygen concentration state. This flow rate may be further divided into more steps or may be set variable so that the gas supply can be performed with fine steps in accordance with measurement results of the oxygen concentration described later in order to effectively suppress the oxygen concentration in the internal space of the EFEM unit 1. The nitrogen supply unit 23 as well as the flow rate controller 519 (see FIG. 6) described later serves as a gas supply system configured to supply a predetermined gas to the circulating path and to change the flow rate of the gas in the present invention.

Nitrogen supplied to the EFEM unit 1 is drawn by a fan filter unit (FFU) 13 arranged in the nitrogen circulating path, passes through a first path 15 and a second path 17 that constitute the nitrogen circulating path, and then returns to the FFU 13. Nitrogen from which dust or the like is removed by the FFU 13 is sent toward the delivery zone 11 in a down flow manner by the FFU 13 and further subjected to electrostatic removal through an ionizer 27. Thus, nitrogen is used for maintaining the cleanliness of the delivery zone 11. Although nitrogen is used in this embodiment, various other gases may be used so long as the gas is a so-called inert gas that decreases the oxygen concentration and does not affect a metal of wiring or the like. In addition, although the configuration using the ionizer 27 is instantiated in this embodiment, this configuration may be omitted depending on the required cleanliness or the like.

The nitrogen supply unit 23 described above is connected to the first path 15 that has the smallest flow path cross-sectional area in the nitrogen circulating path, and supplies nitrogen to the first path 15. The first path 15 has a small cross-sectional area, and hence flow speed of the gas in the first path 15 is relatively higher as compared to the other paths, with the result that a back flow of nitrogen is unlikely to occur and a suitable diffusion of nitrogen in the path can be also expected. Further, an oxygen concentration measurement port 29 and a pressure measurement port 31 are connected to the delivery zone 11. More specifically, each of the ports 29 and 31 has an opening at a position corresponding to a height of transporting a wafer (not shown) to be transported in the delivery zone 11 or a position corresponding to a wafer to be arranged on the lower side of a pod described later when the pod is opened, and measures the oxygen concentration or the pressure at that position. The oxygen concentration measurement port 29 and the pressure measurement port 31 are connected to an oxygen concentration meter 515 and a pressure gauge 517, respectively. With this configuration, an environment where the wafer is placed can be directly measured.

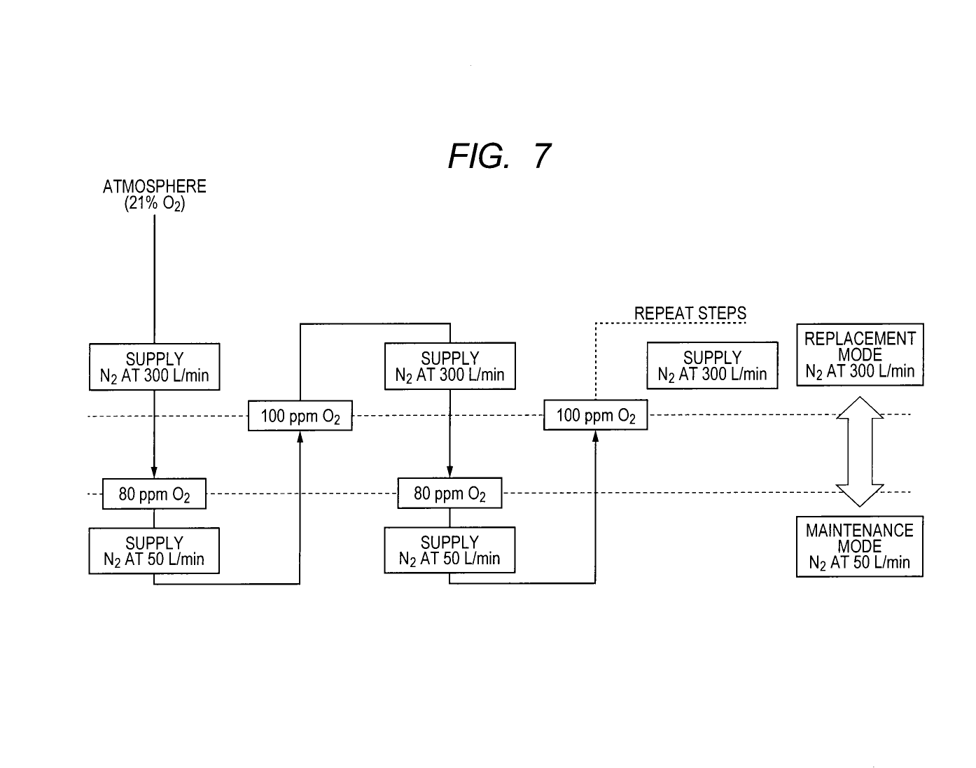

The control unit 5 includes a determination unit 521 and a switching unit 523. Measurement results of the oxygen concentration meter 515 that measures the oxygen concentration in the EFEM unit 1 and the pressure gauge 517 are sent to the determination unit 521 included in the control unit 5, and are compared to multiple threshold values set in advance. A comparison result from the determination unit 521 is sent to the switching unit 523 on the subsequent stage, and the switching unit 523 switches setting so that nitrogen flows at a flow rate set in the flow rate controller 519 in accordance with the above-mentioned threshold values. FIG. 7 illustrates a flow of an example of such a switching step. Firstly, at the time of starting the EFEM unit 1, nitrogen is supplied at the high flow rate to the inside of the EFEM unit 1 in which the oxygen concentration level is that in the atmosphere (21%). The measurement of the oxygen concentration is repeated at predetermined time intervals while maintaining this state, and when the determination unit 521 determines that the oxygen concentration is a second threshold value of 80 ppm or lower, the switching unit 523 switches the nitrogen supply amount set in the flow rate controller 519 to the low flow rate. The measurement of the oxygen concentration is repeated again in this state. Note that, the time interval for repeating the measurement may be changed from the earlier time interval. It is preferred that the change of the time interval be also performed by the switching unit 523 in accordance with the oxygen concentration.

Along with the elapse of time, the oxygen concentration is increased due to inflow of the air followed by an opening and closing operation of the pod 401 or the like. However, when the determination unit 521 determines that the value of the oxygen concentration exceeds a first threshold value of 100 ppm, the switching unit 523 switches again the supply of nitrogen to the high flow rate. In this example, the first threshold value is set to a value larger than the second threshold value. Through the above-mentioned operation, the oxygen concentration is decreased, and when the oxygen concentration becomes lower than the above-mentioned threshold value of 50 ppm, the switching unit 523 switches again the supply of nitrogen to the low flow rate. With this configuration, the oxygen concentration inside the EFEM unit 1 can be suitably maintained while suppressing the supply amount of nitrogen. The flow rates of nitrogen and the threshold values as presented herein are mere examples, and hence it is preferred that these values be appropriately adjusted depending on the oxygen concentration required at an actual semiconductor manufacturing process, a volume of the EFEM unit 1, and the like. Further, a threshold value is also set for the pressure measured by the pressure gauge 517 in a similar manner to the oxygen concentration, and hence opening and closing of the release valve 25 is executed in accordance with the threshold value.

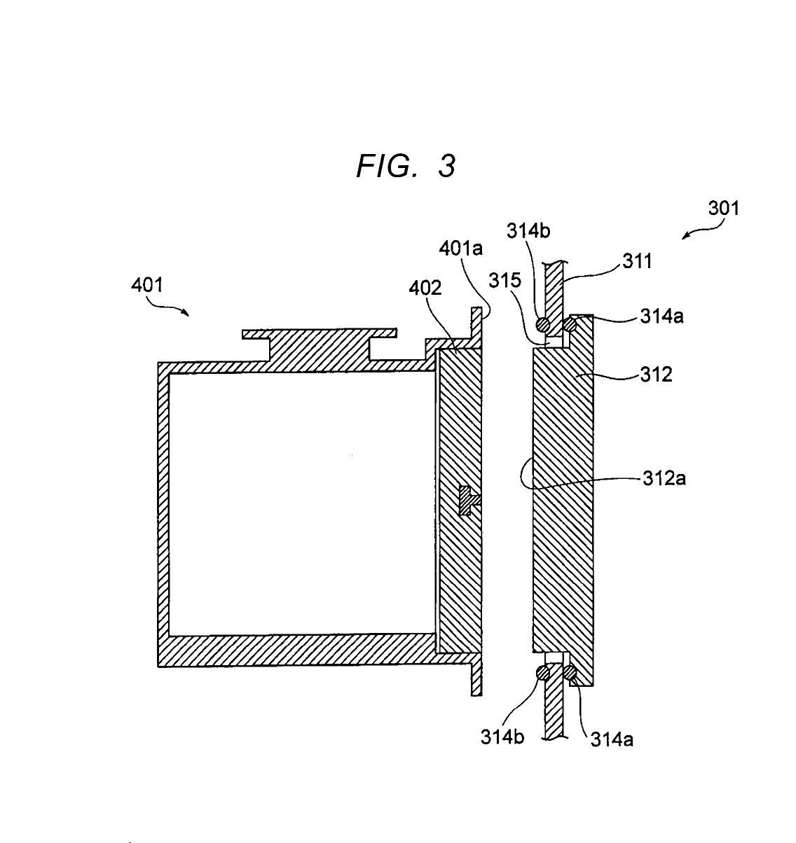

The load port unit 3 is arranged as an interface between the delivery zone 11 and the external space. In this embodiment, three load port units (LPUs) 301 are arranged as the load port unit 3, and the internal space of the pod 401 and the delivery zone 11 are communicated to each other by opening the lid 402 of the pod (see the pod 401 illustrated in FIG. 3 or the like) by each of the LPUs 301. Each of the LPUs 301 includes an LPU base 311 having the LPU base opening portion 315 (the above-mentioned opening portion) as the above-mentioned first opening portion and functioning as one wall surface of the delivery zone 11, the LPU door 312 that opens or closes the LPU base opening portion 315, and the LPU mounting table 316 on which the pod 401 is mountable, for performing approach and separation of the pod 401 to and from the LPU base opening portion 315. That is, the LPU base 311 serves as a wall for isolating the external space and the delivery zone 11 from each other. The LPU door 312 performs the above-mentioned opening and closing of the LPU base opening portion 315 and fixing and unfixing of the lid 402 to and from the pod 401, thus removing and mounting the lid 402 from and to the pod 401.

The opening and closing of the lid 402 of the pod 401 that contains a wafer or the like that is an object to be contained, i.e., the removal of the lid 402 is performed by the LPU door 312. That is, the LPU door 312 can hold the lid 402 of the pod 401, and by opening the LPU base opening portion 315 under a state of holding the lid 402, the inside of the pod 401 and the delivery zone 11 are communicated to each other. With this configuration, the object to be contained can be delivered from the pod 401 to the delivery zone 11. A door drive mechanism (not shown) that drives the LPU door 312 to perform the opening and closing of the LPU base opening portion 315 and a transportation robot 21 that performs insertion and removal of a wafer (not shown) to and from the inside of the pod 401 are arranged in the delivery zone 11. The transportation robot 21 performs the transportation of the wafer right below the FFU 13 in the delivery zone 11, and further performs insertion and removal of a wafer (not shown) to and from a processing chamber (not shown) via an interface 19 on the processing chamber side. Although a so-called SCARA type and a single axis type are used in combination for the transportation robot 21 in this embodiment, the present invention is not limited to this scheme, but various robots may be used.

In this embodiment, in order to prevent the level of the nitrogen atmosphere in the EFEM unit 1 from being decreased, a first O-ring 314a is arranged as a first sealing member between the LPU door 312 and the LPU base 311 along an outer circumference of the LPU base opening portion 315. The delivery zone 11 in the EFEM unit 1 is sealed with respect to the external space by the first O-ring 314a. In addition, a second O-ring 314b corresponding to a pod sealing surface 401a of the pod 401 is arranged on a wall of the LPU base 311 on the external space side along the outer circumference of the LPU base opening portion 315.

The second O-ring 314b corresponds to a second sealing member according to the present invention. The sealing surface is brought into abutment against the second O-ring 314b and nips the second O-ring 314b with the LPU base 311, thus spatially isolating the inside of the pod 401 from the external space when the lid 402 is opened. That is, when the pod 401 is not at a lid opening and closing position, the EFEM unit 1 is separated from the external space by the first O-ring 314a, and when the pod 401 is at the lid opening and closing position, the EFEM unit 1 and the inside of the pod 401 are separated from the external space by the second O-ring 314b. In other words, the first sealing member 314a secures tightness between the LPU door 312 and the LPU base 311 in the delivery zone 11, and the second sealing member 314b secures tightness between the pod 401 and the LPU base 311 in the external space. Although a so-called O-ring is used as the sealing member in this embodiment, the sealing member is not limited to the O-ring so long as the sealing member is a member having a similar sealing function.

The LPU door 312 is described next. In the present invention, as illustrated in FIG. 3, an LPU door abutment surface 312a of the LPU door 312, which is a surface that is brought into abutment against the lid 401, protrudes toward the pod 401 side from an imaginary plane defined by a portion of the second sealing member 314b, which is brought into abutment against the pod sealing surface 401a of the pod 401. In other words, the abutment surface 312a that is a surface of the LPU door 312 on the external space side protrudes toward the external space side with respect to an imaginary plane defined by a sealing region of the second sealing member 314b.

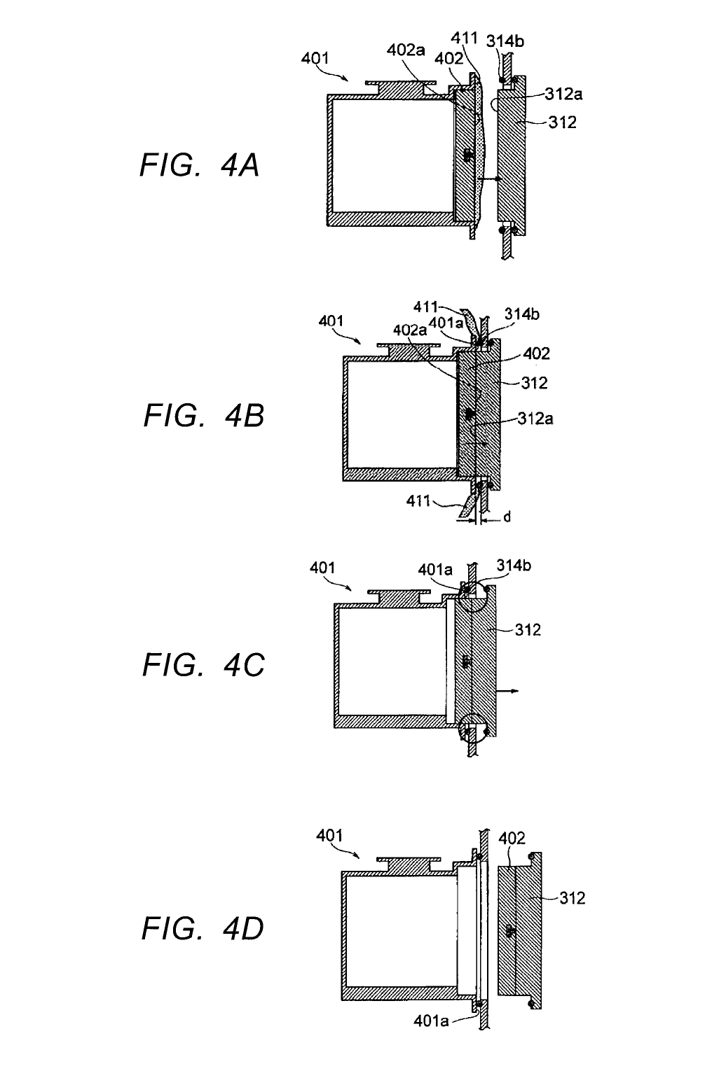

Steps of actually mounting and fixing the pod 401 and removing the lid 402 with respect to the LPU 301 having the above-mentioned configuration are described. FIGS. 4A to 4D schematically illustrate a series of the steps. Normally, the pod 401 is transported in a so-called clean room and mounted on the LPU mounting table 316. However, the cleanliness of the clean room in which the pod 401 is transported is lower than that of the delivery zone 11, and hence as indicated by the first step of FIGS. 4A to 4D, for example, a contaminant adheres to or floats around an outer surface of the lid 402 in a form of a dust or the like 411.

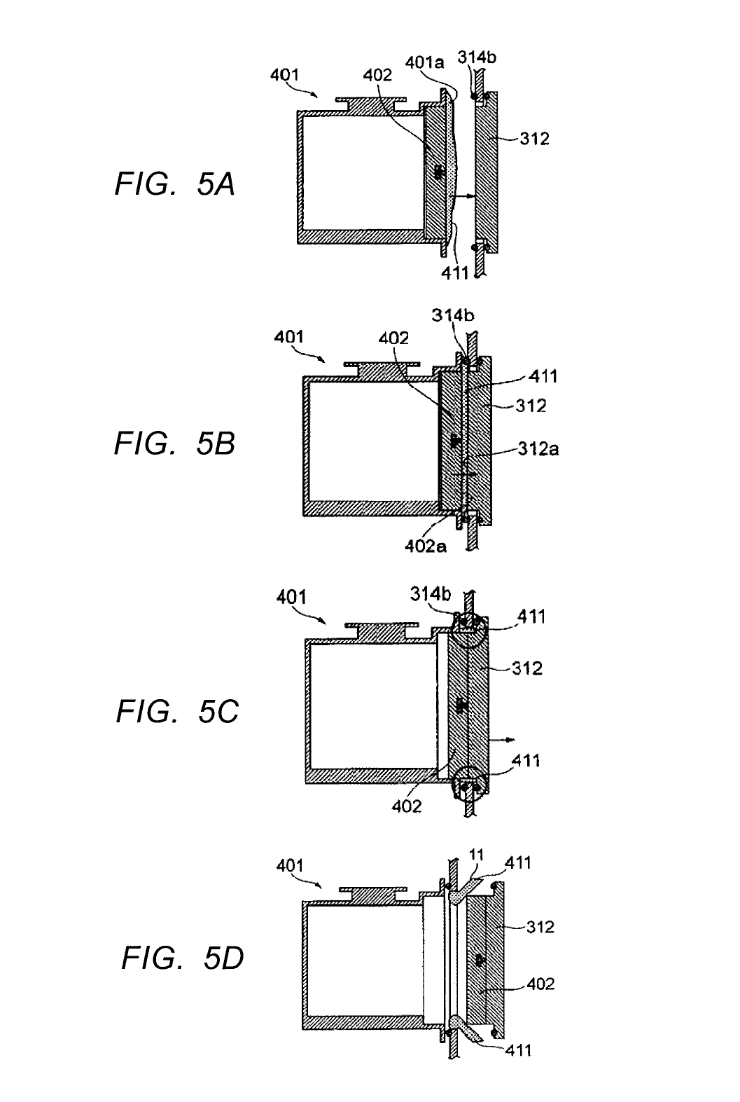

A case of opening the lid 402 by using a related-art load port unit under a state in which the dust or the like 411 adheres to the lid 402 is described with reference to FIGS. 5A to 5D. FIGS. 5A to 5D illustrate a sequence of steps of removing the lid in a similar manner to the steps illustrated in FIGS. 4A to 4D. In the related art, the above-mentioned imaginary plane defined by the second sealing member 314b is configured to protrude from the LPU door 312 with respect to the pod 401. When a surface 402a of the lid 402 is brought close to the outer surface of the LPU door 312 under a state indicated as the first step in FIGS. 5A to 5D, as indicated as the next step in FIGS. 5A to 5D, the dust or the like 411 that adheres to or floats around the surface of the lid 402 is collected in a space enclosed by the surface 312a of the LPU door 312, the surface 402a of the lid 402, and the second sealing member 314b.

When the pod 401 is brought further close to the LPU door 312 so that the surface 402a of the lid 402 is brought into abutment against the LPU door surface 312a, the collected dust or the like moves to a minute gap enclosed by an outer circumferential surface of the LPU door 312 and the first and second sealing members 314a and 314b, and as indicated as the next step in FIGS. 5A to 5D, the dust or the like is further collected in the gap. When the LPU door 312 releases the lid 402 from the pod 401 and is retracted into the delivery zone 11 under this state, the dust or the like 411 collected in the minute gap as indicated as the last step in FIGS. 5A to 5D is drawn into the delivery zone 11, and hence there is a risk in that the inside of the delivery zone 11 is contaminated.

In contrast to this, in the present invention, the abutment surface 312a of the LPU door 312 that is brought into abutment against the lid 402 is arranged to protrude toward the pod 401 side from the above-mentioned imaginary plane defined by the second sealing member 314b. Hence, when the pod 401 is brought close to the LPU door 312, the lid 402 is brought close to the LPU door 312 first, and the lid 402 and the LPU door 312 are brought into abutment against each other while narrowing an interval therebetween. At this time, the dust or the like 411 that floats around the surface of the lid 402 at the first step in FIGS. 4A to 4D is pressed out to the external space from the outer circumference of the lid 402 as the interval is narrowed, and as indicated as the next step in FIGS. 4A to 4D, the surface 402a of the lid 402 and the LPU door abutment surface 312a are brought into abutment against each other under a state in which the dust or the like 411 therebetween is excluded.

Under the abutment state illustrated in FIGS. 4A to 4D, a latch mechanism (not shown) that fixes the lid 402 to the pod 401 is released by a latch switching mechanism (not shown, driven by the door drive mechanism 322) of the LPU door 312, and at the same time, the lid 402 is held by the LPU door 312. Subsequently, operations of retracting the LPU door 312 to the delivery zone 11 (hereinafter simply referred to as “retraction”) by the door drive mechanism 322 and advancing the pod 401 by the mounting table drive mechanism 326 via the synchronization control unit 513 in synchronization with the retraction operation are performed.

As indicated as the last step in FIGS. 4A to 4D, the retraction of the LPU door 312 is performed until the lid 402 held by the LPU door 312 is received in the delivery zone 11. Further, the operation of advancing the pod 401 by the LPU mounting table 316 in synchronization with the retraction of the LPU door 312 is performed until the pod sealing surface 401a of the pod 401 is brought into abutment against the second sealing member 314b. That is, the synchronization control unit 513 drives, via the door drive mechanism 322 and the mounting table drive mechanism 326, the pod 401 toward the LPU base opening portion 315 in synchronization with the operation of the LPU door 312 after the LPU door 312 is brought into abutment against and holds the lid 402.

With the above-mentioned configuration, the dust or the like 411 drawn into the delivery zone 11 only exists at a slight region and its periphery on the outer circumferential surface of the lid 402 that is in a constantly opened state, and hence the dust or the like 411 is greatly reduced as compared to the related-art configuration. Although the synchronization control unit 513 is arranged in the control unit so that the synchronization control is performed based on a program in this embodiment, the present invention is not limited to this scheme. For example, a timer-like configuration may be used, which is arranged in the LPU 301 and operates in accordance with the retraction operation of the LPU door 312, and a mechanical configuration may be used alternatively. Further, although the first sealing member 314a is arranged on the LPU door 312, the first sealing member 314a may be arranged on the LPU base 311. Although the second sealing member 314b of this embodiment is preferred from a standpoint of preventing a contamination at the time of transportation from affecting the sealing member, the second sealing member 314b may be arranged on the pod 401. In addition, the synchronization control unit 513 may take synchronization between the determination unit 521 and the switching unit 523 described above. That is, it is preferred that the synchronization control unit function only when it is detected that the oxygen concentration reaches a threshold value or lower, which is set in advance. With this configuration, the transportation of the wafer or the like is executed only when the internal environment of the EFEM unit 1 is shifted into a suitable operation environment.

As described above, the present invention relates to the load port unit suitable for a semiconductor processing apparatus and the EFEM system including the load port unit. However, the applicability of the present invention is not limited to the semiconductor processing apparatus, but the present invention is also applicable to a so-called load port unit to be used for various processing apparatus configured to perform various processes comparable to those for the semiconductor, such as a processing apparatus for handling a liquid crystal display panel, and also to a so-called EFEM system including the load port unit.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

What is claimed is:

1. A load port unit configured to remove a lid from a pod that contains an object therein, and to take the object from the pod to a delivery zone, the load port unit comprising:
a base serving as a wall for isolating the delivery zone from an external space;
an opening portion formed in the base;
a door configured to open and close the opening portion, and to mount and remove the lid to and from the pod by fixing and unfixing the lid to and from the pod;
a first sealing member configured to secure a tightness between the door and the base in the delivery zone; and
a second sealing member configured to secure a tightness between the pod and the base in the external space,
wherein a surface of the door on the external space side protrudes toward the external space side with respect to an imaginary plane defined by a sealing region of the second sealing member.

2. A load port unit according to claim 1, further comprising a synchronization control unit configured to drive the pod toward the opening portion in synchronization with an operation of the door after the door holds the lid in abutment against the lid.

3. An equipment front end module (EFEM) system configured to be connected to a processing chamber for performing a process on an object via an interface on the processing chamber side, the EFEM system comprising:
the interface on the processing chamber side;
the load port unit according to claim 1; and
an EFEM unit configured to supply an inert gas to the delivery zone by circulating the inert gas through a fan filter unit.

4. An EFEM system according to claim 3, further comprising a release valve configured to discharge an excess inert gas when a supply amount of the inert gas supplied to the delivery zone is excessive.

5. An equipment front end module (EFEM) system configured to be connected to a load port unit, which is configured to remove a lid from a pod that contains an object therein, and to take the object from the pod to a delivery zone, and also connected to a processing chamber for performing a process on the object via an interface on the processing chamber side, the EFEM system comprising:
the interface on the processing chamber side;
a circulating path including the delivery zone and configured to circulate a gas through a fan filter unit;
an oxygen concentration meter configured to measure an oxygen concentration of the gas circulating through the circulating path;
a gas supply system configured to supply a predetermined gas to the circulating path, and to change a supply amount of the predetermined gas; and
a release valve configured to discharge the gas existing in the circulating path to outside,
wherein when the oxygen concentration of the gas is larger than a first threshold value, the gas supply system is configured to increase a flow rate of the predetermined gas to be supplied, and the release valve is configured to discharge the gas, and
wherein when the oxygen concentration of the gas is smaller than a second threshold value that is smaller than the first threshold value, the gas supply system is configured to decrease the flow rate of the predetermined gas.

6. An EFEM system according to claim 5, wherein the predetermined gas comprises an inert gas.

7. An EFEM system according to claim 5, wherein the oxygen concentration meter is arranged at a height corresponding to the object arranged on a lower side among the objects contained in the pod.

8. An EFEM system according to claim 5,
wherein the gas supply system comprises a mass flow valve, and
wherein the gas supply system is configured to supply the predetermined gas in a region of the circulating path, in which a flow path cross-sectional area is decreased.
